(19) United States
(12) Patent Application Publication
(10) Pub. No.: US 2026/0303058 A1
(43) Pub. Date: Oct. 1, 2026

(54) ACOUSTIC WAVE RESONATOR

(71) Applicant: Teknologian tutkimuskeskus VTT Oy, Espoo (FI)

(72) Inventor: Tuomas PENSALA, Espoo (FI)

(21) Appl. No.: 18/873,979

(22) PCT Filed: Jun. 1, 2023
(86) PCT No.: PCT/FI2023/050310

§ 371 Date: Dec. 11, 2024

(30) Foreign Application Priority Data
Jun. 14, 2022 (FI) 20225530

(51) Int. Cl. H03H 9/13; H03H 9/17

(52) U.S. Cl. CPC H03H 9/132; H03H 9/174; H03H 9/176

(57) ABSTRACT

An acoustic wave resonator comprising a piezoelectric layer and a drive electrode and a counter-electrode connected to the piezoelectric layer. The counter-electrode is adjacent to the drive electrode and the counter-electrode, and the drive electrode together delimit a resonance region in the piezoelectric layer. The piezoelectric layer is made of a single-crystal piezoelectric material.

### FIELD OF THE DISCLOSURE

This disclosure relates to piezoelectric resonators, and more particularly to resonators where an electric field applied to a piezoelectric material induces an acoustic wave in the material.

### BACKGROUND OF THE DISCLOSURE

Piezoelectric acoustic resonators can be used for detecting the properties or contents of a medium which is in close contact with the surface of the resonator. An alternating electric field can be used to excite alternating mechanical movement in the piezoelectric material, which in turn can generate standing acoustic waves in the material. At certain resonance frequencies the amplitude of these standing waves will exhibit resonance peaks. This resonator can then be used as an indicator of a mechanical property of the medium or the presence of an analyte in the medium. A change in the viscosity of the medium may for example shift the resonance frequency. Alternatively, if the surface of the resonator has been selective functionalized to promote the absorption of a selected analyte, a shift in the resonance frequency can indicate the presence of that analyte in the medium.

Piezoelectric materials can allow one or more different acoustic resonance modes to be excited in the material. The properties of the resonance modes are determined by the crystal structure of the piezoelectric material, the direction of the electric field in relation to predominant crystal structures, and the thickness of the piezoelectric material in the direction of the electric field. Some resonance modes will be more useful for detecting the properties or contents of a medium than others. For example, if the medium is a liquid medium, resonance modes where the mechanical particle movement in the piezoelectric material is perpendicular to the surface of the resonator will typically dissipate too much energy to achieve a sufficiently high-quality factor Q. The quality factor which can be obtained in resonance modes where the particle motion occurs parallel to the surface of the resonator is typically significantly higher.

Quartz crystal microbalances are widely used as acoustic resonators, but these devices are quite large, and the resonance frequencies are typically limited to a few MHz. Documents WO2019158721 and US2020011835 disclose acoustic resonators which contain thin-film piezoelectric layers deposited on a substrate. Thin-films facilitate resonance frequencies in the GHz range.

However, a general problem with thin-film materials is that their crystal structures cannot be easily optimally aligned with the surface of the underlying substrate. It is therefore difficult to build a thin-film acoustic resonator where particle motion parallel to an outer surface can be strongly excited and clearly isolated from other movements. The figure of merit (FOM=K²*Q, where K² is the electromechanical coupling coefficient and Q the quality factor of resonance) which can be achieved with these resonators is therefore not optimal, and relatively complicated excitation and detection arrangements may be needed to obtain sufficient sensitivity.

### BRIEF DESCRIPTION OF THE DISCLOSURE

An object of the present disclosure is to provide an apparatus which alleviates the above disadvantages.

The object of the disclosure is achieved by an arrangement which is characterized by what is stated in the independent claims. The preferred embodiments of the disclosure are disclosed in the dependent claims.

The disclosure is based on the idea of utilizing a thin single-crystal piezoelectric layer in an acoustic resonator. An advantage of this arrangement is that the layer can be chosen with a specific crystal cut, so that strong particle movement can be generated with surface electrodes in a direction which is parallel to the surfaces of the piezoelectric layer.

### BRIEF DESCRIPTION OF THE DRAWINGS

In the following the disclosure will be described in greater detail by means of preferred embodiments with reference to the accompanying drawings, in which

FIGS. 1a-1c illustrate acoustic wave resonators where a vertical standing acoustic wave can be generated.

FIGS. 2a-2h illustrate different device designs for a resonator with a vertical wave.

FIGS. 3a-3b illustrate acoustic wave resonators where a horizontal standing acoustic wave can be generated.

FIG. 3c illustrates a device design for a resonator with a horizontal wave.

### DETAILED DESCRIPTION OF THE DISCLOSURE

This disclosure describes an acoustic wave resonator comprising a piezoelectric layer with a horizontal first surface and a horizontal second surface. The second surface is opposite to the first surface in a vertical direction. The resonator also comprises a drive electrode connected to the first surface of the piezoelectric layer and a counter-electrode connected to the first or second surface of the piezoelectric layer. The counter-electrode is adjacent to the drive electrode and the counter-electrode, and the drive electrode together delimit a resonance region in the piezoelectric layer. The drive electrode and counter-electrode are connected to a control circuit. The thickness of the piezoelectric layer is in the range 0.1-20 μm. The piezoelectric layer is made of a single-crystal piezoelectric material. The piezoelectric material has a crystal structure which allows an alternating voltage signal between the drive electrode and the counter-electrode to create horizontal particle oscillation in the piezoelectric layer. In other words, the piezoelectric material is configured so that an alternating voltage signal between the drive electrode and the counter-electrode creates horizontal particle oscillation in the piezoelectric layer. The piezoelectric layer may be prepared by growing a single-crystal piezoelectric ingot and then cutting the ingot into thin wafers. The wafers may be polished after cutting to smoothen their surfaces and further reduce their thickness. The orientation of the cut with respect to the crystal structure of the single-crystal ingot will determine the orientation of the crystal structure with respect to the top and bottom surfaces of the wafer. Not all cuts will allow horizontal particle oscillation to be generated. The cut can be chosen with a specific configuration in mind for the surface electrodes, so that the crystal structure in the wafer will support particle movement parallel to the surfaces of the wafer. This movement can generate a standing acoustic wave which oscillates in shear mode. The electrodes and the standing acoustic wave can then form an electric resonator where changes in the resonance frequency can be used as an indicator of changes in an adjacent medium, as described above.

Several different crystal cuts may facilitate the production of horizontal particle movement with surface electrodes. For example, if the piezoelectric material is lithium tantalate (LiTaO₃), then either YX or X crystal cuts can be used, and others are also possible. If the piezoelectric material is lithium niobate (LiNbO₃), then at least the X, Y, and YX cuts support the desired excitation, and other cuts are also possible. Plenty of suitable cuts are typically available and many factors can influence the selection of the optimal cut. These factors include (a) the strength of the coupling between an applied electric field and the particle movement which produces the desired shear oscillation mode, (b) possible unwanted resonances which may be excited along with the desired resonance. Such unwanted resonances can interfere with the desired resonance in the same/nearby frequency range or be formed at other frequencies. And (c) the presence or absence of other resonance modes. For example, the coupling of longitudinal resonance modes should be very low or zero in some applications, but there may be other applications where a shear-resonance mode should preferably be accompanied by a strong longitudinal resonance mode.

In this disclosure, the plane of the wafer is illustrated as the xy-plane, and the direction which is perpendicular to the plane of the wafer is illustrated as the z-direction. The word “horizontal” refers to a direction or a plane which is parallel to the xy-plane, and the word “vertical” refers to the z-direction. The words “horizontal” and “vertical” thereby only refer to the plane of the wafer and the direction which is perpendicular to that plane. The device could be oriented in any direction with respect to the earth's gravitational field when the device is manufactured or used, so the “horizontal” plane of the wafer does not have to be perpendicular to that field.

Two embodiments will be presented. In both embodiments the single-crystal piezoelectric material can for example be LiNbO₃, LiTaO₃ or any other single-crystal material which can be cut with a structure which supports the desired horizontal particle movement.

In all embodiments presented below, the resonator may further comprise a carrier layer which is attached to the piezoelectric layer. The carrier layer may comprise a cavity which extends through the carrier layer to the piezoelectric layer. The cavity is aligned with the resonance region in the piezoelectric layer.

The carrier layer could be attached either to the first surface of the piezoelectric layer or to the second surface of the piezoelectric layer. The carrier layer provides structural support for the piezoelectric layer. The carrier layer may for example be a silicon wafer. The acoustic wave resonator which comprises the carrier layer may be manufactured from a piezo-on-insulator wafer where an insulating layer lies between a thin piezoelectric layer and a thick carrier wafer. The carrier layer may contain through-holes, vias or connections to an electric circuit which lies on another substrate or on a printed circuit board or elsewhere on the carrier layer.

The piezoelectric layer may be a self-supporting layer. It can be sufficiently rigid to retain its structural integrity when the cavity is formed in the carrier layer. The piezoelectric layer can therefore extend across the cavity which is formed in the carrier layer.

In all embodiments presented in this disclosure, the drive electrode and the counter-electrode are connected to a control circuit, and the control circuit is configured to apply an alternating voltage signal between the drive electrode and the counter-electrode. The voltage signal may for example keep the counter-electrode at ground potential while the potential of the drive electrode alternates. The voltage signal sets the molecules of the piezoelectric material in motion, and this motion produces an acoustic wave.

In any embodiments presented in this disclosure, the acoustic wave resonator may be operated by exposing one side of the resonance region to a medium, for example to a liquid medium or a gas medium.

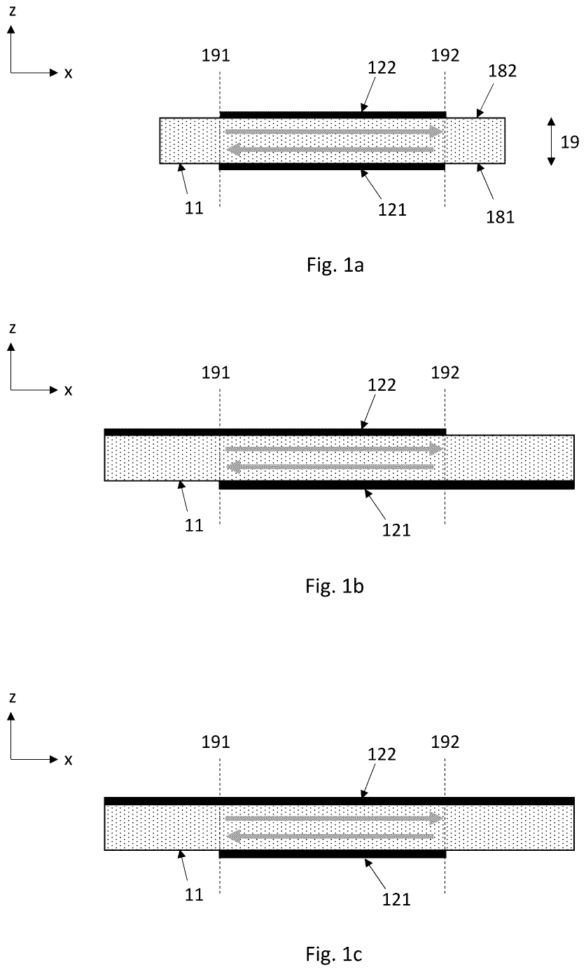

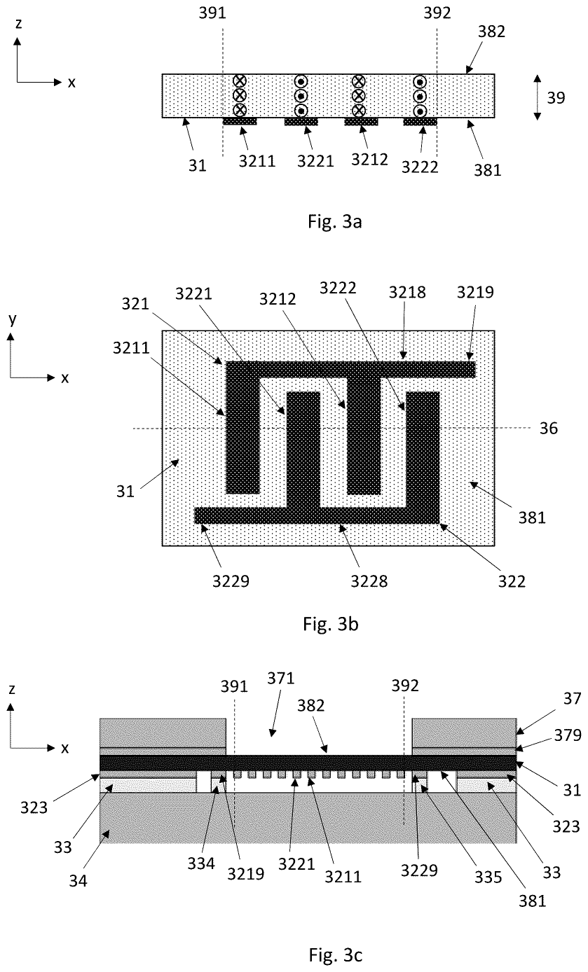

In all embodiments of this disclosure, the thickness (illustrated as 19 and 39 in FIGS. 1a and 3a, respectively) of the piezoelectric layer in the vertical z-direction is in the range 0.1-20 μm. The thickness may be in the range 0.1-10 μm, or in the range 0.1-5 μm or in the range 0.5-10 μm, or in the range 0.5-5 μm, or in the range 0.5-20 μm, or in the range 1-10 μm, or in the range 1-20 μm, or in the range 5-20 μm, or in the range 1-5 μm, or in the range 5-10 μm.

### First Embodiment

The crystal cut can be selected so that the horizontal particle movement is excited by a vertical electric field. The electrodes which apply the electric field to the piezoelectric layer may then be placed adjacent to each other on opposite sides of the wafer. The selection of this crystal cut therefore facilitates an electrode geometry which can be implemented very easily, and the coupling between the electric field and the standing acoustic wave in shear mode resonance will be strong. The shear mode may in this case be called a thickness shear mode or bulk shear mode.

FIG. 1a illustrates an acoustic wave resonator with the properties described above. The resonator includes a piezoelectric layer 11 with a horizontal first surface 181 and a horizontal second surface 182. The second surface 182 is opposite to the first surface 181 in the vertical z-direction. The resonator also comprises a drive electrode 121 connected to the piezoelectric layer 11 and a counter-electrode 122 connected to the piezoelectric layer 11. The counter-electrode 122 is adjacent to the drive electrode 121 (on the opposite side of the piezoelectric layer) and the counter-electrode 122 and the drive electrode 121 together delimit a resonance region 191-192 in the piezoelectric layer 11.

The drive electrode 121 in FIG. 1a is on the first surface 181 of the piezoelectric layer 11. The counter-electrode 122 is on the second surface 182 of the piezoelectric layer 11. The drive electrode is aligned with the counter-electrode in the vertical direction in the resonance region 191-192.

The drive electrode and the counter-electrode do not necessarily have to be confined only to the resonance region. FIG. 1b illustrates a device where both electrodes extend outside of the resonance region 191-192, but they overlap in the vertical direction only in the resonance region. FIG. 1c illustrates a third option.

The particle oscillation which can be generated with this electrode geometry is indicated with grey arrows in FIGS. 1a-1c. The horizontal oscillation occurs in a first direction on the top part of the layer and in a second (opposite) direction on the bottom part of the layer. In other words, the particles which move in the first direction have a first z-coordinate (in the vertical direction) and the particles which move in the second direction have a second z-coordinate, and the first z-coordinate differs from the second. The movement is excited only in the resonance region where there is a vertical electric field between the drive electrode and the counter-electrode. The standing acoustic wave will form in the resonance region in the vertical direction, perpendicular to the first and second surfaces of the piezoelectric layer.

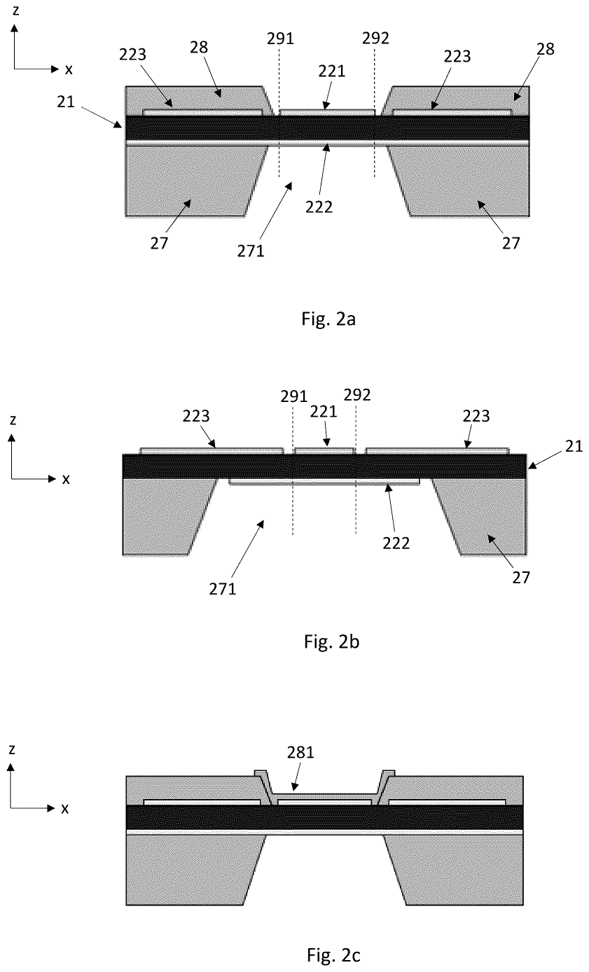

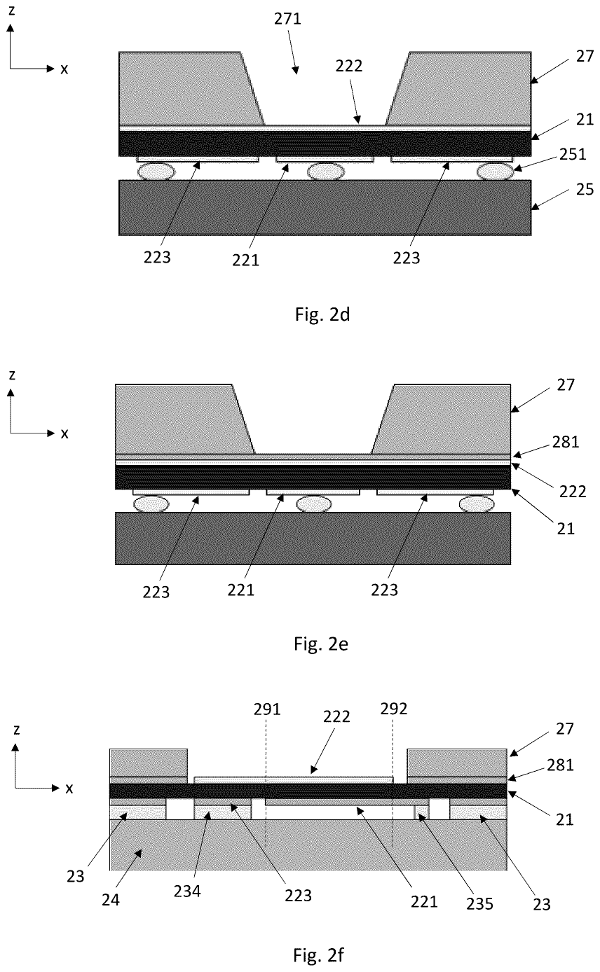

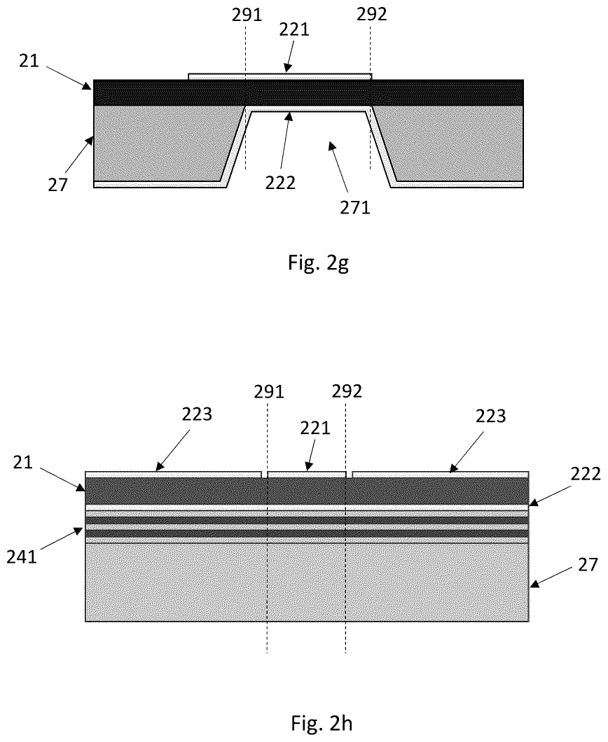

FIG. 2a illustrates an acoustic wave resonator where reference numbers 21, 221-222 and 291-292 correspond to reference numbers 11, 121-122 and 191-192 in FIGS. 1a-1c. The resonator comprises a carrier layer 27 below the piezoelectric layer 21 and a protective passivation layer 28 above the piezoelectric layer 21. The passivation layer may for example be a layer of silicon dioxide. The resonator also contains additional electrodes 223. The counter-electrode 222 may be set to ground potential, and the additional electrodes 223 may be grounded via their capacitive connection to the counter-electrode. Alternatively, both 222 and 223 may be grounded with a direct connection which sets them to ground potential. The counter-electrode 222, which extends beyond the resonance region 291-292 and beyond the cavity 271 formed in the carrier layer 27, may also be set to ground potential. A direct electrical connection may be drawn between the counter-electrode 222 and the additional electrodes 223 either through the piezoelectric layer 21 or at the edges of the resonator.

The device in FIG. 2a may for example be manufactured by depositing the counter-electrode 222 on the carrier layer 27 and then bonding the piezoelectric layer 21 to the carrier layer 27. Electrodes 221 and 223 may then be deposited onto the piezoelectric layer 21. A cavity 271 may be etched in the carrier layer 27 to release the piezoelectric layer 21 and allow acoustic resonance in the resonance region 291-292. The passivation layer 28 may then be deposited on top of the electrodes 221, 223 and an opening may be made also in the passivation layer 28 in the resonance region 291-292.

FIG. 2b illustrates an alternative design where the counter-electrode 222 extends beyond the resonance region 291-292, but not beyond the cavity 271. This device can be manufactured by bonding the piezoelectric layer 21 to the carrier layer 27. The counter-electrode 222 can then be deposited onto the piezoelectric layer 21 after the cavity 271 has been formed in the carrier layer 27. The resonator may in this case also be passivated, for example with a silicon dioxide layer which leaves only the resonator exposed. Additional layers may also be applied to the devices in FIGS. 2a and 2b.

The resonator may be exposed to a medium from the top side illustrated in FIG. 2a, that is, from the side of passivation layer 28. If the drive electrode material is, for example, gold, the drive electrode may be sufficiently resistant to withstand corrosion despite direct exposure. Alternatively, if the electrode material would be vulnerable to corrosion, an additional passivation layer 281 may be deposited over the electrode. If the additional passivation layer 281 is thin enough, the resonator can still be sufficiently sensitive to changes at the interface between the medium and the resonator (for example analyte absorption on the surface of the additional passivation layer). The layer 281 may for example be a silicon dioxide layer or gold layer.

Alternatively, the resonator may be exposed to a medium from the bottom side illustrated in FIG. 2a. FIG. 2d illustrates a resonator which has been flip chip bonded with electric connections 251 to an underlying wafer 25 which may comprise the control circuit. No passivation layers may be needed in this case, and the medium may enter cavity 271 in carrier layer 27 and come into contact with counter-electrode 222 in the resonance region. As in FIG. 2c, an additional passivation layer can if necessary be deposited on top of the counter-electrode if there is a risk that it might degrade when it comes into contact with the medium. FIG. 2e illustrates a resonator where an additional passivation layer 281 has been placed between the carrier layer 27 and the electrode 222. Further passivation layers can, if necessary, be deposited over carrier layer 27.

FIG. 2f illustrates a device where the acoustic wave resonator is integrated with a readout substrate 24, which may for example be a CMOS substrate. The surface of the readout substrate 24 contains metal contacts such as 23, 234 and 235.

The acoustic wave resonator comprises a counter-electrode 222 on the top side of piezoelectric layer 21. The metal contact 234 on the surface of the readout substrate 24 may be connected to an additional electrode 223 on the piezoelectric layer when the acoustic wave resonator is placed on the readout substrate 24. The metal contact 234 and the additional electrode 223 may then be used as a capacitive ground connection for the counter-electrode 222.

The acoustic wave resonator in FIG. 2f also comprises a drive electrode 221 on the bottom side of the piezoelectric layer 21. The drive electrode 221 is connected to metal contact 235 on the readout substrate. A drive signal may be brought to drive electrode 221 through the metal contact 235.

The electrodes on the piezoelectric layer 21 may be bonded to the adjacent and corresponding metal contacts on the readout substrate 24. The acoustic wave resonator may be flip-chip bonded to the readout substrate.

FIG. 2g illustrates another alternative. Here the carrier layer 27 comprises a cavity 271 which extends to the piezoelectric layer 21, and the counter-electrode 222 has been deposited on the bottom surface of the carrier layer. In this case the dimensions of the resonance region 291-292 may be determined by the size of the cavity 271. The drive electrode 221 may extend beyond the resonance region on any side. The passivation solutions shown in FIGS. 2a and 2c can also be implemented in this embodiment. If necessary, additional grounded electrodes may also be implemented, as in the previous figures.

FIG. 2h illustrates a further option where the resonator is a solidly mounted resonator. The piezoelectric layer 21 lies on an acoustic Bragg-interference reflector. Layers 241 form the Bragg-reflector on the top surface of the carrier layer 27 and the acoustic wave resonator is built on top of the reflector. Bragg-reflectors can be implemented at least with the resonator structures shown in FIGS. 2a-2c. A standing vertical wave can then be created in the piezoelectric layer without forming a cavity in the carrier layer.

### Second Embodiment

The crystal cut can alternatively be selected so that the horizontal particle movement is excited by a horizontal electric field on one surface of the piezoelectric layer. The drive and counter-electrodes which apply the electric field to the piezoelectric layer may in this case be placed adjacent to each other on the same side of the wafer. The selection of this crystal cut therefore also facilitates an electrode geometry which can be easily implemented with electrodes on the same surface, and the coupling between the electric field and the standing acoustic wave in shear-mode resonance will be strong. The shear mode may in this case be called a horizontal shear mode or horizontally propagating shear mode.

FIG. 3a illustrates an acoustic wave resonator with the properties described above. The resonator includes a piezoelectric layer 31 with a horizontal first surface 381 and a horizontal second surface 382. The second surface 382 is opposite to the first surface 381 in the vertical z-direction. The resonator also comprises a drive electrode connected to the piezoelectric layer 31 and a counter-electrode connected to the piezoelectric layer 31. The counter-electrode is adjacent to the drive electrode (on the same side of the piezoelectric layer) and the counter-electrode, and the drive electrode together delimit a resonance region 391-392 in the piezoelectric layer 31. Additional reflector electrodes may be added to the left and right of the illustrated electrodes to facilitate the formation of a standing acoustic wave. These reflector electrodes may be grounded.

The particle oscillation which can be generated with this electrode geometry is indicated with symbols in FIG. 3a. The horizontal oscillation occurs in a first direction (into the illustrated xz-plane) on the part of the layer which lies above electrodes 3211 and 3212, and in a second (out of the illustrated xz-plane) direction on the part of the layer which lies above electrodes 3221 and 3222. In regions which are slightly to the right and left of electrodes 3211 and 3212, particle movement will also occur into the plane but with a smaller amplitude. Similarly, in regions which are slightly to the right and left of electrodes 3221 and 3222, particle movement will occur out of the plane but with an amplitude which is smaller than the oscillation amplitude immediately above these electrodes. The standing acoustic wave will form in the resonance region in the horizontal direction, perpendicular to the particle movement.

The drive electrode in FIG. 3a comprises a set of drive finger electrodes 3211, 3212 on the first surface 381 of the piezoelectric layer 31. The counter-electrode comprises a set of counter-finger electrodes 3221, 3222 on the first surface 381 of the piezoelectric layer 31. The set of drive finger electrodes 3211, 3212 is interdigitated in the horizontal direction with the set of counter-finger electrodes 3221, 3222 in the resonance region.

FIG. 3b illustrates the drive and counter-electrode in the xy-plane. The fingers of the drive electrode 321 are interdigitated with the fingers of the counter-electrode 322. The cross-section illustrated in FIG. 3a may for example be the one illustrated with line 36 in FIG. 3b. The drive electrode 321 may for example be connected to the control circuit at a first connection point 3219, and the counter-electrode 322 may correspondingly be connected to the control circuit at a second connection point 3229. The number of fingers in both the drive and counter-electrodes may be greater than two.

FIG. 3c illustrates a device where the acoustic wave resonator is integrated with a readout substrate 34, which may for example be a CMOS substrate. The surface of the readout substrate 34 contains metal contacts such as 33, 334 and 335. Reference numbers 31, 37 and 371 in FIG. 3c correspond to reference number 21, 27 and 271 in FIGS. 2a-2h, and reference number 379 corresponds to reference number 281 in FIGS. 2e-2f.

The drive finger electrodes such as 3211 and the counter-finger electrodes such as 3221 have here been prepared on the bottom side (first surface 381) of the piezoelectric layer 31. The metal contact 334 on the surface of the readout substrate 34 has been connected to the first connection point 3219 on the drive electrode when the acoustic wave resonator was placed on the readout substrate 34. The other metal contact 335 on the readout substrate 34 has been connected to the second connection point 3229. A drive signal can thereby be brought to the drive electrode and counter-electrodes through the metal contact 334 and 335. In other words, the connection points on the electrodes on the piezoelectric layer 31 may be bonded to the adjacent and corresponding metal contacts on the readout substrate 34. Other metal contacts 33 on the readout substrate 34 may be connected to additional electrodes 323 on the piezoelectric layer 31 for grounding purposes. The acoustic wave resonator may be flip-chip bonded to the readout substrate. In FIG. 3c the first surface 381 of the piezoelectric layer faces the readout substrate 34, while the second surface 382 faces the surrounding environment.

Cavity 371 may be open to the surrounding environment, so that a surrounding medium (for example a liquid or gas) can fill the cavity 371. The sides (left and right in FIG. 3c) of the resonator and the readout substrate 34 may be hermetically sealed, so that the medium cannot reach any parts of the device which lie below the first surface 381 of the piezoelectric layer.

Passivation layers may be applied to the top side (second surface 382) of the piezoelectric layer 31 in the same manner as in the first embodiment. The optional passivation layer 379 could for example cover the entire second surface 382 of the piezoelectric layer 31. However, this layer is completely optional. One benefit of the arrangement illustrated in FIG. 3c may be precisely that no electrode structures are needed on the side of the piezoelectric layer which faces cavity 371. The frequency of the resonator may be a more sensitive indicator of the properties of the medium in the cavity when there is no intervening layer between the medium and the piezoelectric layer.

### Practical Applications

The acoustic wave resonator may for example be used as the active component of a surface attachment sensor for liquid solutions. One side of the piezoelectric layer may be exposed to a liquid medium (possibly with an electrode and/or a protective passivation layer in between) which may contain a substance (which may be called the analyte) which would adhere to the surface of the resonator. By driving the sensor in resonance and measuring to what extent its resonance oscillation changes over time, the amount of substance that has adhered to the resonator may be determined.

The acoustic wave resonator may for example be used as the active component of a liquid viscosity sensor. Here too, one side of the piezoelectric layer may be exposed to a liquid medium (possibly with an electrode and/or a protective passivation layer in between). By driving the sensor in resonance measuring to what extent its resonance oscillation changes over time, changes in the viscosity of the liquid may be determined.

1. An acoustic wave resonator comprising
a piezoelectric layer with a horizontal first surface and a horizontal second surface, wherein the second surface is opposite to the first surface in a vertical direction,
a drive electrode connected to the first surface of the piezoelectric layer,
a counter-electrode connected to the first or second surface of the piezoelectric layer,
wherein the counter-electrode is adjacent to the drive electrode and the counter-electrode and the drive electrode together delimit a resonance region in the piezoelectric layer,
and the drive electrode and counter-electrode are connected to a control circuit, characterized in that the thickness of the piezoelectric layer is in the range 0.1-20 μm, and the piezoelectric layer is made of a single-crystal piezoelectric material, and the piezoelectric material has a crystal structure which allows an alternating voltage signal between the drive electrode and the counter-electrode to create horizontal particle oscillation in the piezoelectric layer.

2. The acoustic wave resonator according to claim 1, wherein the drive electrode is on the first surface of the piezoelectric layer and the counter-electrode is on the second surface of the piezoelectric layer, and the drive electrode is aligned with the counter-electrode in the vertical direction in the resonance region.

3. The acoustic wave resonator according to claim 1, wherein the drive electrode comprises a set of drive finger electrodes on the first surface of the piezoelectric layer and the counter-electrode comprises a set of counter-finger electrodes on the first surface of the piezoelectric layer, and the set of drive finger electrodes is interdigitated in the horizontal direction with the set of counter-finger electrodes in the resonance region.

4. The acoustic wave resonator according to claim 1, wherein the resonator further comprises a carrier layer which is attached to the piezoelectric layer, and the carrier layer comprises a cavity which extends through the carrier layer to the piezoelectric layer, and the cavity is aligned with the resonance region in the piezoelectric layer.

5. The acoustic wave resonator according to claim 4, wherein the carrier layer is attached to the first surface of the piezoelectric layer.

6. The acoustic wave resonator according to claim 4, wherein the carrier layer is attached to the second surface of the piezoelectric layer.

7. The acoustic wave resonator according to claim 1, wherein the single-crystal piezoelectric material is LiNbO₃ or LiTaO₃.

8. A surface attachment sensor for liquid solutions comprising an acoustic wave resonator according to claim 1.

9. A liquid viscosity sensor comprising an acoustic wave resonator according to claim 1.
